(19) United States
(12) Patent Application Publication
(10) Pub. No.: US 2014/0179112 A1
(43) Pub. Date: Jun. 26, 2014

(54) High Productivity Combinatorial Techniques for Titanium Nitride Etching

(71) Applicants: Intermolecular Inc., (US); GLOBALFOUNDRIES, (US)

(72) Inventors: John Foster, Mountain View, CA (US); Sven Metzger, Dresden (DE)

(73) Assignees: GLOBALFOUNDRIES, Milpitas, CA (US); Intermolecular Inc., San Jose, CA (US)

(21) Appl. No.: 13/726,760

(22) Filed: Dec. 26, 2012

(51) Int. Cl. H01L 21/306

(52) U.S. Cl. CPC H01L 21/30604
USPC 438/754

(57) ABSTRACT

Provided are methods of High Productivity Combinatorial testing of semiconductor substrates, each including multiple site isolated regions. Each site isolated region includes a titanium nitride structure as well as a hafnium oxide structure and/or a polysilicon structure. Each site isolated region is exposed to an etching solution that includes sulfuric acid, hydrogen peroxide, and hydrogen fluoride. The composition of the etching solution and/or etching conditions are varied among the site isolated regions to study effects of this variation on the etching selectivity of titanium nitride relative to hafnium oxide and/or polysilicon and on the etching rates. The concentration of sulfuric acid and/or hydrogen peroxide in the etching solution may be less than 7% by volume each, while the concentration of hydrogen fluoride may be between 50 ppm and 200 ppm. In some embodiments, the temperature of the etching solution is maintained at between about 40° C. and 60° C.

### BACKGROUND

Titanium nitride has various applications in the semiconductor industry, such as metal barriers, conductive electrodes, metal gates, and many others. Specifically, titanium nitride has good metal diffusion blocking characteristics and low resistivity of about 30-70 micro Ohm-cm after annealing. For example, the new 45 nm chip configuration and beyond makes use of titanium nitride for improved transistor performance. Titanium nitride used in a combination with hafnium oxide or other like materials (used as gate dielectrics) that have a higher permittivity compared to silicon oxide and that can be scaled down without increasing leakage while maintaining and even increasing drive current and threshold voltage.

### SUMMARY

Provided are methods of High Productivity Combinatorial (HPC) testing of semiconductor substrates, each including multiple site isolated regions. High Productivity Combinatorial™ and HPC™ are trademarks of Intermolecular, Inc. Each site isolated region includes a titanium nitride structure as well as a hafnium oxide structure and/or a polysilicon structure. Each site isolated region is exposed to an etching solution that includes sulfuric acid, hydrogen peroxide, and hydrogen fluoride. The composition of the etching solution and/or etching conditions are varied among the site isolated regions to study effects of this variation on the etching selectivity of titanium nitride relative to hafnium oxide and/or polysilicon and on the etching rates. The concentration of sulfuric acid and/or hydrogen peroxide in the etching solution may be less than 7% by volume each, while the concentration of hydrogen fluoride may be between 50 ppm and 200 ppm. In some embodiments, the temperature of the etching solution is maintained at between about 40° C. and 60° C.

In some embodiments, a method for HPC testing of semiconductor substrates involves providing a semiconductor substrate that includes multiple site isolated regions. Each site isolated region includes a first structure and a second structure. The first structure includes titanium nitride, while the second structure includes hafnium oxide, polysilicon, or both. In some embodiments, the substrate includes some site isolated regions with titanium nitride and hafnium oxide structures and some site isolated regions with titanium nitride and polysilicon structures.

The method may proceed with exposing each site isolated region to one or more etching solutions. The etching solution includes sulfuric acid, hydrogen peroxide, and hydrogen fluoride. The etching solution may be water based. Other polar solvents may be used in addition to or instead of water.

The method may proceed with etching the first structure (i.e., the structure including titanium nitride) in each site isolated region using different processing conditions. Differences in the process conditions may include different temperatures of the etching solution and/or site isolated regions, different compositions of the etching solution, different durations of etching, and the like. Furthermore, different types of first structures and/or second structures (e.g., different techniques used to form the titanium nitride structure) may be used in different site isolated regions. The different processing conditions cause different etching selectivities between the first structure and the second structure in different site isolated regions. For purposes of this disclosure, an etching selectivity is defined as a ratio of two etching rates, e.g., an etching rate of the first structure to an etching rate of the second structure.

In some embodiments, each site isolated region is exposed to the same etching solution or, more specifically, to the etching solutions having the same composition. Alternatively, at least one site isolated region may be exposed to an etching solution having a different composition than at least one other site isolated region. For example, a concentration of one or more components (e.g., sulfuric acid, hydrogen peroxide, and hydrogen fluoride) may be varied or an additive may be varied to some but not all etching solutions. In some embodiments, the concentration of sulfuric acid in each etching solution is less than 7% by volume. The concentration of hydrogen peroxide may be also less than 7% by volume. In some embodiments, the concentration of hydrogen fluoride in the etching solutions is between 50 ppm and 200 ppm or, more specifically, about 100 ppm.

In some embodiments, different processing conditions include different processing temperatures or, more specifically, different etching solution temperatures. In other words, at least two site isolated regions processed at different temperatures. For example, one site isolated region may be tested at about 40° C., another one—at about 50° C., and yet another one—at about 60° C. In some embodiments, the temperatures range between 25° C. and 60° C. or, more specifically, between 40° C. and 60° C. The different processing conditions may also include different etching durations used for at least two site isolated regions. Performing etching for different lengths of time may be used to determine etching rates. Because each site isolated region includes two different types of structures (e.g., one including titanium nitride and another one including polysilicon or hafnium oxide), etching selectivities may be determined by comparing etching rates of these two structures. Varying both temperatures and durations may be used to determine etching rates at different temperatures.

The different processing conditions may cause different etching rates of the first structure and the second structure in different site isolated regions. In some embodiments, the processing conditions are varied to achieve a target etching rate of titanium nitride. For example, the target etching rate of titanium nitride may be between about 5 Angstroms per minute and 100 Angstroms per minute or, more specifically, between about 5 Angstroms per minute and 25 Angstroms per minute. In some embodiments, the processing conditions are varied to maximize selectivity between the first structure and the second structure.

Provided also is a method for HPC testing of semiconductor substrates that involves providing a semiconductor substrate including between 20 and 40 site isolated regions. Each site isolated region includes a first structure and a second structure. The first structure includes titanium nitride, while the second structure includes hafnium oxide. The method proceeds with exposing each site isolated region to an etching solution that includes sulfuric acid having a concentration of less than 7% by volume, hydrogen peroxide having a concentration of less than 7% by volume, and hydrogen fluoride having a concentration of between 50 ppm and 250 ppm. The method may then proceed with etching the first structure in each site isolated region using different temperatures of the etching solution in at least some of the site isolated regions.

Provided are methods for HPC testing of semiconductor substrates that involves providing a semiconductor substrate including multiple site isolated regions. Each site isolated region includes a first structure and a second structure. The first structure includes titanium nitride, while the second structure includes polysilicon. The method continues with exposing each site isolated region to one or more etching solutions. Each of the other or more etching solutions includes sulfuric acid, hydrogen peroxide, and hydrogen fluoride. The method continues with etching the first structure in each site isolated region using different etching durations in at least some of the site isolated regions.

These and other embodiments are described further below with reference to the figures.

### BRIEF DESCRIPTION OF THE DRAWINGS

FIG. 1 illustrates a schematic diagram for implementing combinatorial processing and evaluation using primary, secondary, and tertiary screening, in accordance with some embodiments.

FIG. 2 is a simplified schematic diagram illustrating a methodology for combinatorial process sequence integration that includes site isolated processing and/or conventional processing, in accordance with some embodiments.

FIG. 3 illustrates a schematic diagram of a substrate that has been processed in a combinatorial manner, in accordance with some embodiments.

FIG. 4 illustrates a schematic diagram of a combinatorial wet processing system, in accordance with some embodiments.

FIGS. 5A and 5B illustrate schematic representations of semiconductor substrate portions before and after etching, in accordance with some embodiments.

FIG. 6 illustrates a process flowchart corresponding to a method of HPC testing a semiconductor substrate, in accordance with some embodiments.

FIG. 7 illustrates an SEM image of a sample processed using techniques described herein.

FIGS. 8A and 8B are magnified SEM images illustrating a gate stack before and after processing, in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### INTRODUCTION

Scaling of the gate lengths and equivalent gate oxide thicknesses is forcing the replacement of silicon oxide used as a gate dielectric with materials having high-dielectric constants (i.e., high-k materials). The goals include reduction of leakage currents and meeting requirements of reliability. Some additional considerations in selecting suitable replacement materials include silicon related band offsets, permittivity, dielectric breakdown strength, silicon interface stability, and carrier effective masses.

Hafnium oxide, hafnium silicon oxide, and hafnium silicon oxynitride are leading candidates for silicon oxide replacement as gate dielectrics. Titanium nitride may be used for gate electrodes together with these new gate dielectric materials. The new materials demand new processing techniques for integration of these materials into semiconductor devices. For example, the new gate dielectric materials as well the new gate electrode materials may need to be controllably etched in order to shape the overall transistor structure and allow deposition of other materials. Specifically, gate dielectrics and gate electrodes may need to be undercut after their formation to allow for deposition of liners and side spacers.

Ozone oxidation (e.g., 5 ppm of O₃) followed by hydrogen fluoride etching (e.g., 300:1 dilution ratio) has been proposed for applications described above but found to be ineffective and needing expensive materials and long processing. It has unexpectedly been found that a dilute sulfuric acid and hydrogen peroxide (DSP) mixture containing small amounts (e.g., parts-per-million) of hydrogen fluoride works well for the same application. The titanium nitride etching rates can be easily controlled by selecting and monitoring processing temperatures when using this type of etching solutions. Yet, processing windows of this etching process tend to be very narrow and require significant experimentation for each new structure and material type. HPC techniques may be used to quickly and efficiently determine various processing parameters for different materials and applications. While the description below focuses on titanium nitride, hafnium oxide, and/or polysilicon structures, such as the ones found in modern transistor devices, DSP-based etching and HPC techniques may be used for other structures and applications.

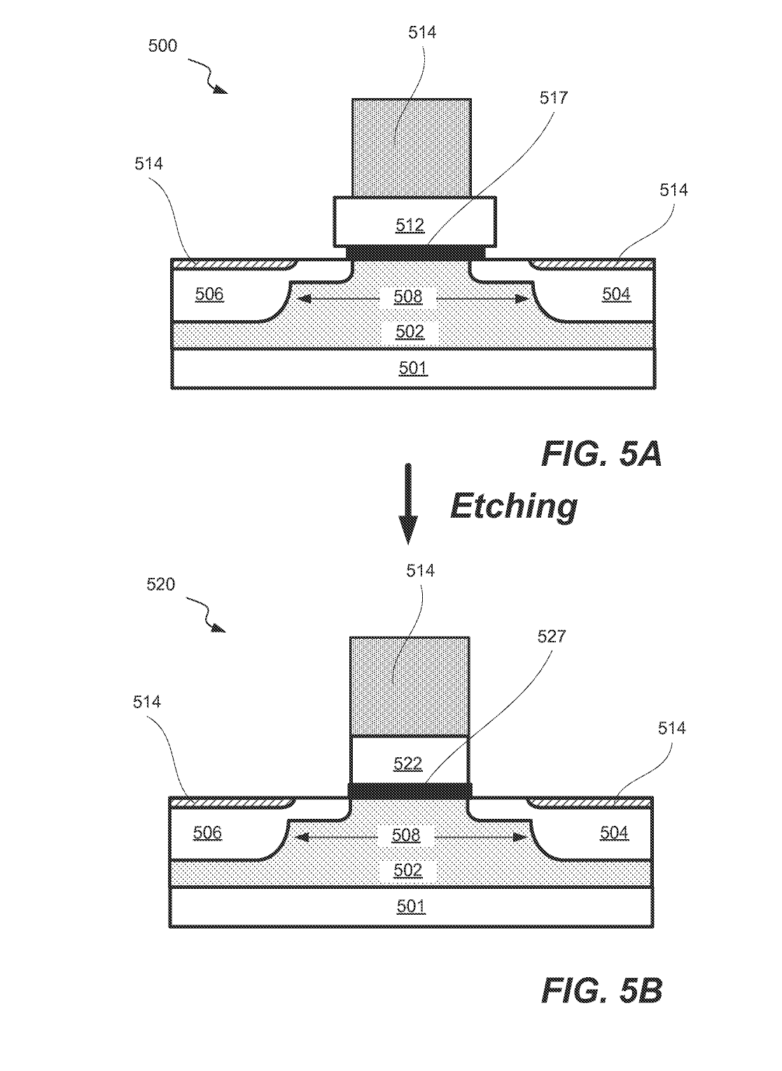

HPC is a promising approach that allows testing different samples, etchants, and/or processing conditions on the same semiconductor substrate. This approach increases testing throughput and likelihood of finding optimum materials for various applications, such as gate dielectrics and gate electrodes. HPC methodology involves parallel processing of multiple site isolated regions provided on a substrate. Each site isolated region may be used for testing different materials and/or processing conditions. For example, a transistor includes a gate electrode and a gate dielectric provided under the gate electrode in addition to other components further described below with reference to FIGS. 5A and 5B. In a typical production process, each one of these components is formed from a separate blanket layer that initially covers the entire substrate. As such, the corresponding components of different transistors fabricated on the same substrate have the same composition, thickness, and are processed using the same conditions. The HPC approach allows varying one or more characteristics of these components among different site isolated regions. For example, etching of the different site isolated regions may be performed using different temperatures, durations, and even etchant compositions.

Provided are methods of HPC testing, in which each site isolated region includes a titanium nitride structure as well as a hafnium oxide structure and/or a polysilicon structure. Each site isolated region is exposed to an etching solution that includes sulfuric acid, hydrogen peroxide, and hydrogen fluoride. The solution may be water based. The concentration of sulfuric acid and/or hydrogen peroxide in the etching solution may be maintained at less than 7% by volume each, while the concentration of hydrogen fluoride may be between 50 ppm and 200 ppm. The composition of the etching solution and/or etching conditions are varied among the site isolated regions to study effects of this variation on the etching selectivity of titanium nitride relative to hafnium oxide and/or polysilicon. For example, a temperature may be varied from one site isolated region to another. In some embodiments, the temperature of the etching solution is maintained at between about 40° C. and 60° C. Another parameter that can be varied is duration of the etching.

### High Productivity Combinatorial (HPC) Examples

HPC generally refers to techniques of differentially processing multiple regions of a substrate. It may involve varying materials, unit processes, process sequences, and other process parameters across multiple regions (referred to as site isolated regions) provided on the substrate. The varied materials, unit processes, or process sequences can be evaluated (e.g., characterized) to determine whether further evaluation is warranted or whether a particular solution is suitable for production or high volume manufacturing.

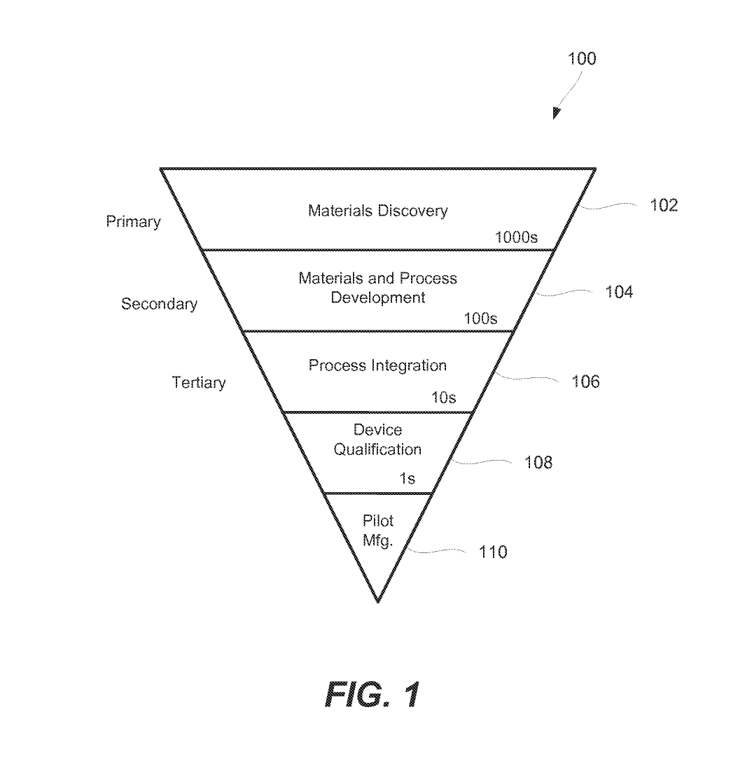

FIG. 1 illustrates a schematic diagram for implementing combinatorial processing and evaluation using primary, secondary, and tertiary screening, in accordance with some embodiments. Specifically, diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage 104. Evaluation of the materials is performed using metrology tools such as electronic testers and imaging tools (i.e., microscopes).

Materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106, where tens of materials and/or processes and combinations are evaluated. Tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

Diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways. Additional aspects of High Productivity Combinatorial (HPC) techniques are described in U.S. patent application Ser. No. 11/674,137, filed on Feb. 12, 2007, which is hereby incorporated by reference in its entirety for purposed of describing HPC techniques.

The embodiments described further analyze a portion or sub-set of the overall process sequence used to manufacture a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

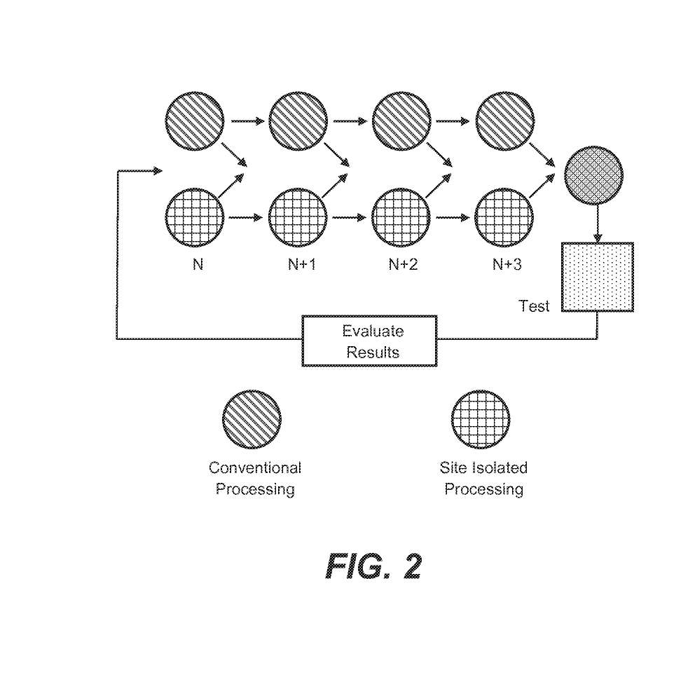

FIG. 2 is a simplified schematic diagram illustrating a general methodology for combinatorial process sequence integration that includes site isolated processing and/or conventional processing, in accordance to some embodiments. The substrate may be initially processed using conventional process N. In some embodiments, the substrate is then processed using site isolated process N+1. During site isolated processing, an HPC module may be used, some examples of which are described below. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in one embodiment or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

Combinatorial processing can be used to produce and evaluate different materials, chemicals, processes, process and integration sequences, and techniques related to semiconductor fabrication. For example, combinatorial processing can be used to determine optimal processing parameters (e.g., power, time, reactant flow rates, temperature, etc.) of dry processing techniques such as dry etching (e.g., plasma etching, flux-based etching, reactive ion etching (RIE)) and dry deposition techniques (e.g., physical vapor deposition (PVD), chemical vapor deposition (CVD), atomic layer deposition (ALD), etc.). Combinatorial processing can be used to determine optimal processing parameters (e.g., time, concentration, temperature, stirring rate, etc.) of wet processing techniques such as wet etching, wet cleaning, rinsing, and wet deposition techniques (e.g., electroplating, electroless deposition, chemical bath deposition, etc.).

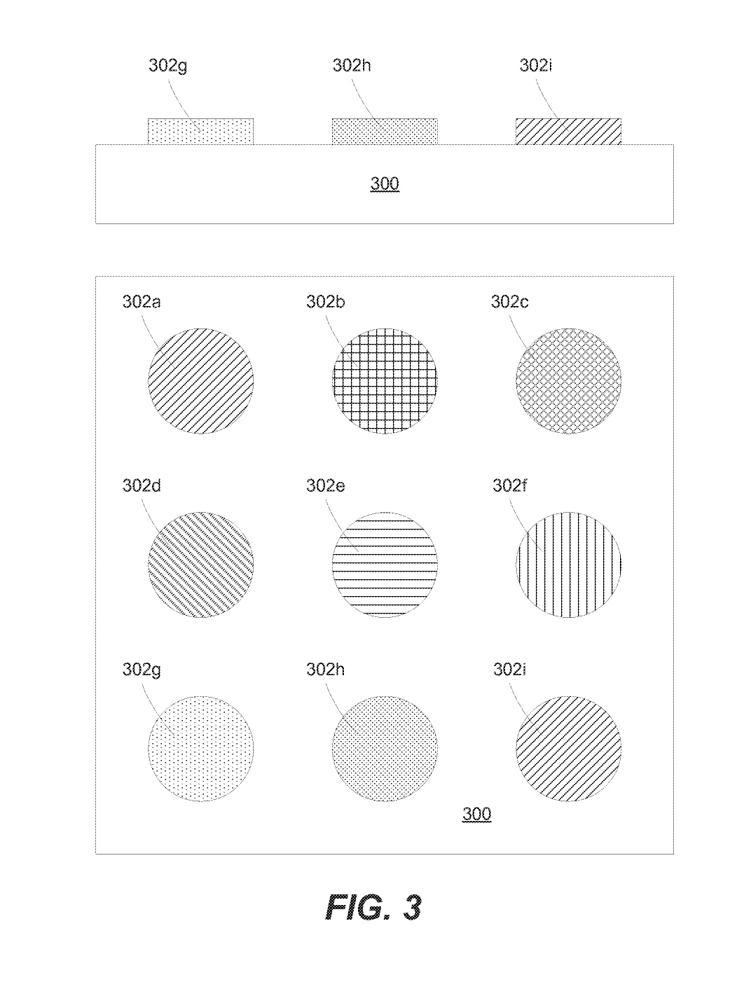

FIG. 3 illustrates a schematic diagram of a substrate 300 processed in a combinatorial manner, in accordance with some embodiments. Substrate 300 is shown to have nine site isolated regions 302a-302i. Although substrate 300 is illustrated as being a generally square shape, those skilled in the art will understand that the substrate may be any useful shape such as round, rectangular, etc. The lower portion of FIG. 3 illustrates a top down view while the upper portion of FIG. 3 illustrates a cross-sectional view taken through the three site isolated regions 302g-302i. The shading of the nine site isolated regions illustrates that the process parameters used to process these regions have been varied in a combinatorial manner. The substrate may then be processed through a next step that may be conventional or may also be a combinatorial step as discussed earlier with respect to FIG. 2. One having ordinary skills in the art would understand that the substrate may include any number of the site isolated regions, e.g., between about 20 and 40 or, more specifically, 28. All site isolated regions may be processed using different processing conditions. In some embodiments, two or more site isolated regions may be processed using the same processing conditions. For purposes of this disclosure, processing conditions are defined as any parameter that may impact on the outcome of the process. For example, in the etching context, processing parameters may include parameters of the etched materials (e.g., geometry, composition), composition of etching solution, processing temperature, duration, pre- and post-etching operations, and the like.

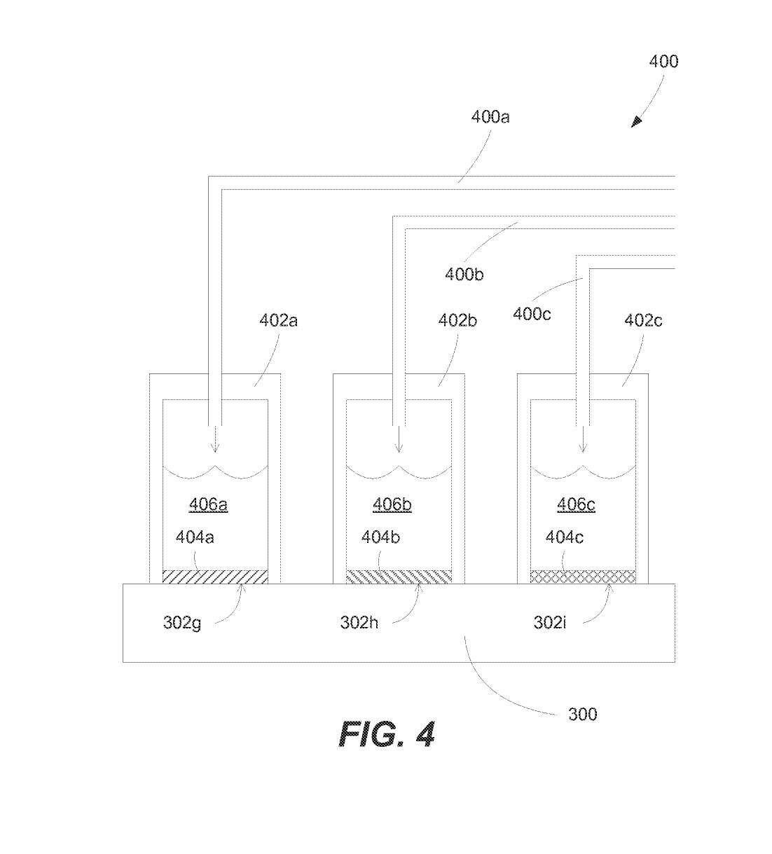

FIG. 4 illustrates a schematic diagram of a combinatorial wet processing system 400, in accordance with some embodiments. System 400 may be used to investigate materials deposited or, more generally, processed using solution-based techniques. Those skilled in the art would understand that this is only one possible configuration of a combinatorial wet system. FIG. 4 illustrates a cross-sectional view of substrate 300 taken through the three site isolated regions 302g-302i similar to the upper portion of FIG. 3 described above. Solution dispensing nozzles 400a-400c supply solutions 406a-406c having the same or different compositions (i.e., different solution chemistries 406a-406c) to chemical processing cells 402a-402c. FIG. 4 illustrates the deposition of layers 404a-404c within respective site isolated regions 302g-302i. Although FIG. 4 illustrates a deposition step, other solution-based processes such as cleaning, etching, surface treatment, surface functionalization, and the like may be investigated in a combinatorial manner. The solution-based treatment can be customized for each of the site isolated regions.

### Semiconductor Device Examples

A brief description of semiconductor device examples is presented below to provide better understanding of various processing features. Specifically, FIGS. 5A and 5B illustrate schematic representations of substrate portions including MOS device 500 before etching and the same device 520 after etching of its gate electrode, in accordance with some embodiments. The references below are made to PMOS devices but other types of devices can be used as well and will be understood by one having ordinary skill in the art. PMOS device 500 may include a p-doped substrate 501 and an n-doped well 502 within substrate 501. Substrate 501 is typically a part of an overall wafer substrate together with other transistors and devices. P-doped substrate 501 may include any suitable p-type dopants, such as boron and indium, and may be formed by any suitable technique. N-doped well 502 may include any suitable n-type dopants, such as phosphorus and arsenic, and may be formed by any suitable technique. N-doped well 502 may be formed by doping substrate 501 by ion implantation, for example.

Device 500 also includes a conductive gate electrode 512 that is separated from n-doped well 502 by gate dielectric 517. Gate electrode 512 may be formed from titanium nitride. In some embodiments, gate electrode 512 may also include a polysilicon sub-layer (not shown) provided between titanium nitride sub-layer and gate dielectric. Gate electrode 512 can be used for circuit interconnection, such as interconnecting other gates, other devices, and to directly contacting the underlying single crystal silicon. Titanium nitride has good contact resistance characteristics to silicon, copper, and aluminum. Further, the titanium nitride portion of gate electrode 512 can be plasma etched with a reactive ion etch system that is anisotropic.

While titanium nitride has relatively good resistance to oxidation, the oxidation resistance can be improved by forming a silicon structure 514 over gate electrode 512. Silicon structure 514 may be formed from a continuous film that is selectively removed for making metal contacts, where desired, or, if the silicon is heavily doped, metal contact can be made directly to the silicon. The thin layer of silicon can thus insure good contact between contact lines deposited on the wafers subsequent to the gate electrode and interconnect formation.

Gate electrode 512 that includes titanium nitride may be formed using CVD or ALD techniques. For example, a substrate may be heated to between about 500-800° C. and titanium tetrachloride, ammonia, and hydrogen gas may be provided to the surface of the substrate. The volumetric flow ratio of these gases may 1:4:5 for the order of the gases listed above. The chamber may be maintained at 100 to 300 mTorr resulting in a growth rate of 20-40 Angstroms per minute. The overall thickness of gate electrode may be between 200 Angstroms and 100 Angstroms. The resistivity of titanium nitride deposited according to such process may be between 50 and 150 micro Ohm-centimeter. After the deposition, the titanium nitride structure may be annealed in situ at a temperature between 900° C. and 1000° C. for approximately 5-30 minutes in a nitrogen atmosphere in order to reduce the resistivity below 50 micro Ohm-centimeter.

Gate dielectric 517 may be formed from silicon oxide, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, yttrium oxide aluminum oxide, lead scandium tantalum oxide, or lead zinc niobate. Gate dielectric 517 may be formed using CVD or ALD processes. In some embodiments, gate dielectric is formed from hafnium oxide, hafnium silicon oxide, or hafnium silicon oxynitride.

Device 500 also includes p-doped source region 504 and drain region 506 (or simply the source and drain) in n-doped well 502. Source 504 and drain 506 are located on each side of gate 512 forming channel 508 within well 502. Source 504 and drain 506 may include a p-type dopant, such as boron. Additionally, source 504 and drain 506 may be formed in recesses of n-doped well 502. Source 504 and drain 506 may be formed using, for example, ion implantation. After the source and drain formation, the overall substrate may be subjected to an annealing and/or activation thermal process.

Portions of gate electrode 512 may need to be removed to allow conformal deposition of liners and sidewall spacers. At the same time excessive removal may damage the overall device. FIG. 5B illustrates device 520 after etching illustrating modified gate electrode 512. In some embodiments, the same process also modifies other components, such as gate dielectric 527.

### Processing Examples

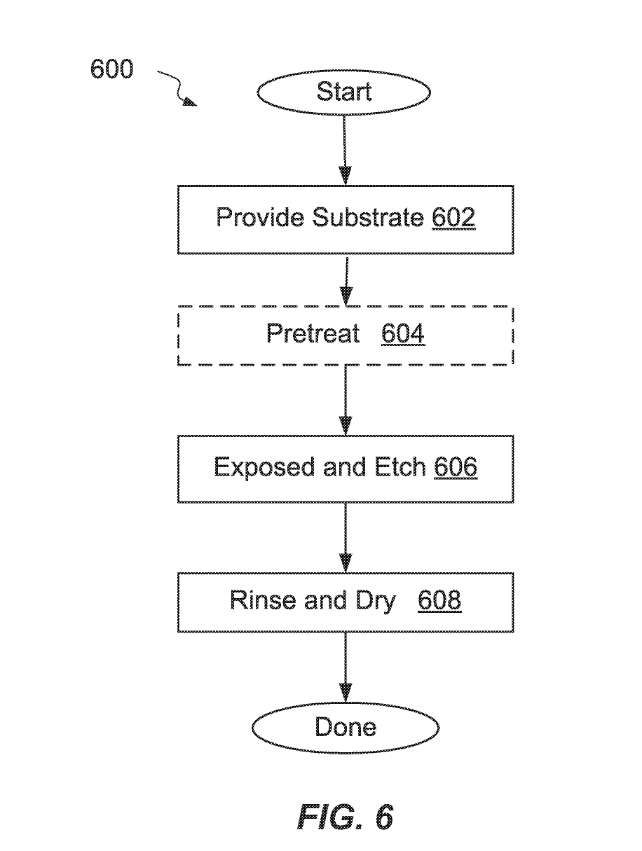

FIG. 6 illustrates a process flowchart corresponding to method 600 for high HPC testing of semiconductor substrates, in accordance with some embodiments. Method 600 may commence with operation 602, during which a semiconductor substrate including multiple site isolated regions is provided. Each site isolated region includes at least two structures: a first structure formed from titanium nitride and a second structure formed from hafnium oxide or polysilicon. In some embodiments, the first structure and/or the second structure may include other materials. Furthermore, some or all site isolated regions may include other structures (i.e., in addition to the first structure and the second structure). Various examples of structures are described above with reference to FIGS. 5A and 5B.

Method 600 may proceed with an optional pretreatment operation 604. In some embodiments, pretreatment operation 604 may also involve exposing the substrate to a hydrofluoric acid solution. The dilution ratio of this solution may be between 100:1 to 500:1 or, more specifically, about 300:1 by volume. The duration of this exposure may be between about 0.5 minutes and 5 minutes or, more specifically, between about 1 minute and 3 minutes, such as about 100 seconds. This exposure should be distinguished from the etching operation 606 when the substrate is exposed to an etching solution including sulfuric acid, hydrogen peroxide, and hydrogen fluoride. The hydrofluoric acid exposure may be followed by deionized water rinse (e.g., about 180 seconds) to remove residual cleaning solution.

Operations 604 may be performed using the same processing conditions for the entire substrate. In other words, operation 604 may be applied without using HPC techniques described above. In some embodiments, processing conditions using during operation 604 may vary from one site isolated region to another.

Method 600 may proceed with exposing the semiconductor substrate to an etching solution and etching the first structure in each site isolated region using different processing conditions during operation 606. These different processing conditions cause different etching selectivities between the first structure and the second structure in different site isolated regions. In other words, a ratio of the first structure etch rate to the second structure etch rate varies among the site isolated regions. This may be achieved by having different first structure etch rates, different second structure etch rates, or both.

The different processing conditions may involve different compositions of the etching solution, different processing temperatures, different etch durations and/or different materials of the first structure and/or of the second structure. In some embodiments, two or more process conditions may vary during processing of the same substrate (e.g., processing temperatures and etch durations). For example, the etch durations may vary from 20 seconds to 90 seconds, such as 20 seconds, 30 seconds, 40 seconds, 50 seconds, 60 seconds, 75 seconds, and 90 seconds. The processing temperature may vary from 25° C. to 60° C., such as 25° C., 40° C., 45° C., 50° C., 55° C., and 60° C.

In some embodiments, each site isolated region is exposed to the same etching solution or, more specifically, to the same composition of the etching solution. For example, KDSP-100 etching solution supplied by Kanto Corporation in Portland, Oreg.) may be used. The concentration of sulfuric acid in the etching solution may be less than 7% by volume, while the concentration of hydrogen peroxide may be also less than 7% by volume. In some embodiments, the concentration of hydrogen fluoride in the etching solution may be between 50 ppm and 200 ppm or, more specifically, about 100 ppm. The etching solution may be water based. In some embodiments, the composition of the etching solutions may vary from one site isolated region to another one. For example, a concentration of hydrofluoric may vary between 50 ppm and 200 ppm or some other range.

The processing conditions may be varied to achieve a target etching rate of titanium nitride. In some embodiments, the target etching rate of titanium nitride is between about 5 Angstroms per minute and 100 Angstroms per minute or more specifically between about 5 Angstroms per minute and 25 Angstroms per minute. The processing conditions may be also varied to maximize selectivity between the first structure and the second structure.

After completion of operation 206, method 200 may proceed with rinsing and drying the substrate during operation 208. In some embodiments, a hydrogen chloride rinse may be used. The conditions used for this hydrogen chloride etching may be the same as described above. The residual etching solution is removed from the substrate surface during this operation by, for example, rinsing the surface with deionized water and drying with an inert gas, such as nitrogen or argon.

### Experimental Results

A series of experiments were conducted to determine impact of etching temperature and duration on removal of titanium nitride formed using PECVD. Polysilicon structures provided adjacent to the titanium nitride structures were used as references. All samples were etched using a mixture of sulfuric acid, hydrogen peroxide, and hydrogen fluoride to selectively etch the titanium nitride structures. Different temperatures and durations were used. The temperatures were varied form 25° C. to 60° C., while the durations were varied from 30 seconds to 90 seconds. The same solution (i.e., KDSP-100 supplied by Kanto Corporation in Portland, Oreg.) was used for all tests and samples. The solution included between about 7-11% sulfuric acid and hydrogen peroxide each, and 100 ppm of hydrofluoric acid. The test was performed using an HPC apparatus capable of independently testing 28 site isolated regions on the same substrate similar to the one described above with reference to FIG. 4. The tested samples were then subjected to 180-second rinse using deionized water and 450-second rinse using hydrochloric acid prior to inspection. Some samples were generated without using hydrochloric acid rinses to investigate their impact on the TiN etch.

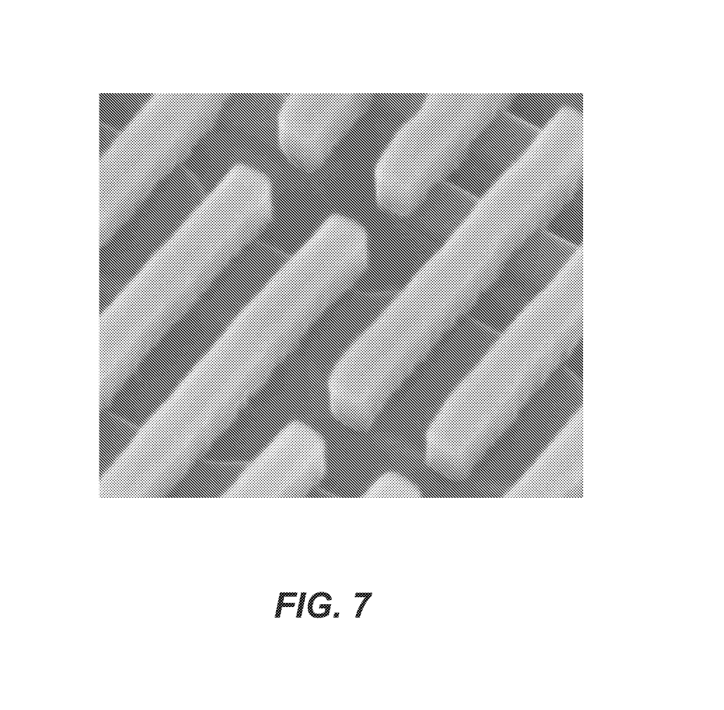

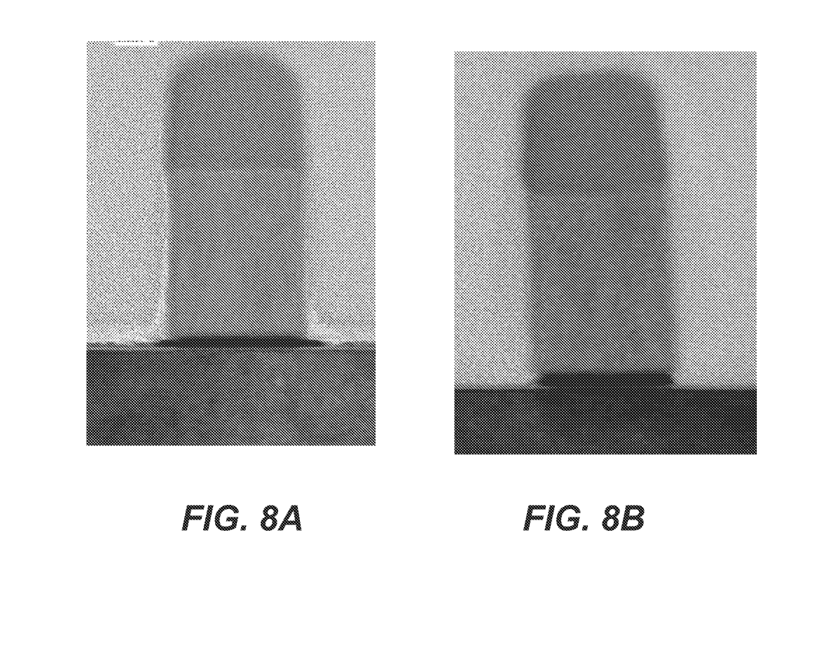

FIG. 7 illustrates an SEM image of a samples etched for 75 seconds at 50° C. The gates and active areas are very clean as it can easily assessed from this image. The titanium nitride structures were adequately recessed and etched residues were removed. There were no indications of polysilicon deterioration. It should be noted that some aggressive chemistries (e.g., higher concentrations of hydrofluoric acid in a combination with hydrogen peroxide, such as 0.3% by volume each) can deteriorate silicon to the extent that the gates can topple. FIGS. 8A and 8B are magnified SEM images illustrating a gate stack before (FIG. 8A) and after (FIG. 8B) processing in accordance to the above-referenced test protocol. The comparison of these SEM images provides more detailed illustration of the degree of titanium nitride undercut and damage (or lack thereof) to polysilicon.

Titanium nitride etch rates for three different temperatures (i.e., 40° C., 50° C., and 60° C.) were estimated using different etching durations (i.e., 30 seconds, 60 seconds, and 90 seconds). Specifically, the etch rate at 40° C. was found to be about 7.7 Angstroms per minute, at 50° C.—about 26.7 Angstroms per minute, and at 60° C.—about 32.6 Angstroms per minute.

### CONCLUSION

Although the foregoing concepts have been described in some detail for purposes of clarity of understanding, it will be apparent that some changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A method for high productivity combinatorial (HPC) testing of semiconductor substrates, the method comprising:
providing a semiconductor substrate comprising multiple site isolated regions,
each site isolated region comprising a first structure and a second structure,
the first structure comprising titanium nitride, and
the second structure comprising one of hafnium oxide or polysilicon;
exposing each site isolated region to one or more etching solutions,
each of the one or more etching solutions comprising sulfuric acid, hydrogen peroxide, and hydrogen fluoride; and
etching the first structure in each site isolated region, wherein process conditions for the etching are varied in a combinatorial manner among the multiple site isolated regions.

2. The method of claim 1, wherein each site isolated region is exposed to the same etching solution.

3. The method of claim 1, wherein at least one site isolated region is exposed to an etching solution having a different composition than at least one other site isolated region.

4. The method of claim 1, wherein a concentration of sulfuric acid in each of the one or more etching solutions is less than 7% by volume.

5. The method of claim 1, wherein a concentration of hydrogen peroxide in each of the one or more etching solutions is less than 7% by volume.

6. The method of claim 1, wherein a concentration of hydrogen fluoride in each of the one or more etching solutions is between 50 ppm and 200 ppm.

7. The method of claim 1, wherein the different processing conditions cause different etching selectivities between the first structure and the second structure in different site isolated regions.

8. The method of claim 1, wherein each of the one or more etching solutions further comprises water.

9. The method of claim 1, wherein the different processing conditions comprise different etching solution temperatures.

10. The method of claim 9, wherein the different etching solution temperatures range from 40° C. to 60° C.

11. The method of claim 1, wherein the different processing conditions comprise different etching durations used.

12. The method of claim 11, wherein the different etching durations range from 30 seconds to 90 seconds.

13. The method of claim 1, wherein the different processing conditions cause different etching rates of the first structure and the second structure in different site isolated regions.

14. The method of claim 13, wherein the processing conditions are varied to achieve a target etching rate of titanium nitride.

15. The method of claim 14, wherein the target etching rate of titanium nitride is between about 5 Angstroms per minute and 25 Angstroms per minute.

16. The method of claim 13, wherein the processing conditions are varied to maximize selectivity between the first structure and the second structure.

17. The method of claim 1, wherein the second structure comprises hafnium oxide.

18. The method of claim 1, wherein the second structure comprises polysilicon.

19. A method for high productivity combinatorial (HPC) testing of semiconductor substrates, the method comprising:
providing a semiconductor substrate comprising between 20 and 40 site isolated regions,
each site isolated region comprising a first structure and a second structure,
the first structure comprising titanium nitride, and
the second structure comprising hafnium oxide;
exposing each site isolated region to an etching solution,
the etching solution comprising sulfuric acid having a concentration of less than 7% by volume, hydrogen peroxide having a concentration of less than 7% by volume, and hydrogen fluoride having a concentration of between 50 ppm and 250 ppm; and
etching the first structure in each site isolated region using different temperatures of the etching solution in at least some of the site isolated regions.

20. A method for high productivity combinatorial (HPC) testing of semiconductor substrates, the method comprising:
providing a semiconductor substrate comprising multiple site isolated regions,
each site isolated region comprising a first structure and a second structure,
the first structure comprising titanium nitride, and
the second structure comprising polysilicon;
exposing each site isolated region to one or more etching solutions,
each of the other or more etching solutions comprising sulfuric acid, hydrogen peroxide, and hydrogen fluoride; and
etching the first structure in each site isolated region using different etching durations in at least some of the site isolated regions.
